(19) United States
(12) Patent Application Publication
(10) Pub. No.: US 2007/0052025 A1
(43) Pub. Date: Mar. 8, 2007

(54) Oxide semiconductor thin film transistor and method of manufacturing the same

(75) Inventor: Hisato Yabuta, Tokyo (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 11/511,263

(22) Filed: Aug. 29, 2006

(30) Foreign Application Priority Data
Sep. 6, 2005 (JP) 2005-258276

(51) Int. Cl. H01L 27/12

(52) U.S. Cl. 257/347; 438/479; 257/E29.117

(57) ABSTRACT

Provided is a thin film transistor comprising a channel layer comprised of an oxide semiconductor containing In, M, Zn, and O, M including at least one selected from the group consisting of Ga, Al, and Fe. The channel layer is covered with a protective film.

### BACKGROUND OF THE INVENTION

1. Field of the Invention

The present invention relates to a thin film transistor (TFT) in which an oxide semiconductor containing In, M, Zn, and O, where M represents at least one of Ga, Al, and Fe, is used for a channel layer and a method of manufacturing the thin film transistor.

2. Description of the Related Art

In recent years, there is an attempt to form a transparent film as a channel layer of a transistor using a conductive oxide thin film. For example, a TFT in which a polycrystalline thin film of a transparent conductive oxide containing ZnO as a main ingredient is used for the channel layer is under active development (see JP 2002-076356 A) The thin film can be formed at low temperatures and is transparent to visible light, so it is assumed that a flexible transparent TFT can be formed on a substrate such as a plastic plate or a film.

However, when a ZnO thin film is used for the channel layer, there is such a disadvantage that it is difficult to manufacture a normally-off TFT. In order to overcome this disadvantage, a TFT in which an InMO₃(ZnO)ₘ thin film (M=In, Fe, Ga, or Al) is used for the channel layer is proposed (see JP 2004-103957 A).

### SUMMARY OF THE INVENTION

The inventors et al. of the present invention manufactured TFTs in which an oxide semiconductor containing In, M, Zn, and O, where M represents at least one of Ga, Al, and Fe, is used for a channel layer, and then evaluated the manufactured TFTs. As a result, it is found that the TFTs are sensitive to atmospheres and thus characteristics thereof are changed by an atmosphere during operation or storage.

Therefore, an object of the present invention is to provide a device with high reliability and reduced unstability of TFT characteristics which is caused by a change in atmosphere, in a TFT in which the oxide semiconductor containing In, M, Zn, and O, where M represents at least one of Ga, Al, and Fe, is used for the channel layer, unstability of TFT characteristics which is caused by a change in atmosphere.

To attain the above-mentioned object, a thin film transistor according to the present invention is characterized by including a channel layer comprised of an oxide semiconductor containing In, M, Zn, and O, M representing at least one selected from the group consisting of Ga, Al, and Fe; and a protective film that covers the channel layer.

According to the present invention, in a normally-on TFT in which an oxide semiconductor containing In, M, Zn, and O, where M represents at least one of Ga, Al, and Fe, such as a transparent oxide thin film, is used for the channel layer, covering the channel layer with a protective film prevents an unstable operation caused by the change in atmosphere. Therefore, stable TFT operational characteristics are obtained. Thus, the unstability of TFT characteristics which is caused by the change in atmosphere can be reduced to provide a device having high performance, stability, and reliability.

Other features and advantages of the present invention will be apparent from the following description taken in conjunction with the accompanying drawings, in which like reference characters designate the same or similar parts throughout the figures thereof.

Further features of the present invention will become apparent from the following description of exemplary embodiments with reference to the attached drawings.

### BRIEF DESCRIPTION OF THE DRAWINGS

The accompanying drawings, which are incorporated in and constitute a part of the specification, illustrate embodiments of the invention and, together with the description, serve to explain the principles of the invention.

FIG. 1 is a schematic view showing a structure of a top gate TFT according to Example 1 to Example 3 of the present invention.

FIG. 2 is a graph showing a transfer characteristic of the TFT according to Example 1 to Example 3 of the present invention.

FIG. 3 is a graph showing transfer characteristics of a conventional TFT in the atmosphere and under vacuum for comparison with FIG. 2.

FIG. 4 is a schematic view showing a structure of a top gate TFT according to Example 4 of the present invention.

### DESCRIPTION OF THE EMBODIMENTS

The inventors of the present invention manufactured TFTs in which an oxide semiconductor containing In, M, Zn, and O, where M represents at least one of Ga, Al, and Fe, is used for a channel layer and then evaluated the manufactured TFTs. As a result, it is found that the TFTs are sensitive to atmospheres and thus characteristics thereof are changed by an atmosphere during operation or storage.

That is, one of the manufactured TFT devices is placed in a vacuum chamber and the conductivity thereof is measured while evacuating the vacuum chamber. As a result, a phenomenon is observed in which the value as measured is gradually reduced with a reduction in pressure. When the same measurement is performed on another TFT device, the value as measured at a reduced pressure is larger than that in the atmosphere in contrast to the case of the above-mentioned TFT device. In the case of each of the TFT devices, the measured values of conductivity are stable when measurement is performed in a normal atmosphere.

The change in conductivity which is caused by atmospheres is observed even in a case where another conductive oxide such as a zinc oxide (ZnO) or an indium tin oxide (ITO) is used. This may be caused by absorption and desorption of, for example, moisture, other gas molecules, or the like to and from a conductive oxide in an atmosphere.

Therefore, in the TFT in which the oxide semiconductor containing In, M, Zn, and O, where M represents at least one of Ga, Al, and Fe, is used for the channel layer, the change in conductivity due to the change in atmosphere is caused, so the TFT operation becomes unstable. As a result, there is a problem in which reliability of a device cannot be obtained.

The thin film transistor using an oxide semiconductor channel according to the present invention is a thin film transistor in which an oxide semiconductor containing In, M, Zn, and O, where M represents at least one of Ga, Al, and Fe, is used for the channel layer. The channel layer is covered with a protective film.

According to the present invention, the protective film may be a metal oxide film containing at least one kind of metal element. The protective film may be a film including at least one selected from the group consisting of a silicon nitride, a silicon oxide, and a silicon carbide. The protective film may be an organic substance film. The protective film may be a multilayer film comprised of an organic substance film and a metal film.

According to the present invention, a gate dielectric film of the thin film transistor may be made of a yttrium oxide. The gate dielectric film of the thin film transistor may include at least one selected from the group consisting of a yttrium oxide, an aluminum oxide, a hafnium oxide, a zirconium oxide, and a titanium oxide.

According to the present invention, the protective film may include a microvoid formed therein.

Hereinafter, best modes of thin film transistors according to the present invention and methods of manufacturing the thin film transistors will be described with reference to the accompanying drawings.

### First Embodiment

The structure of a TFT device including a thin film transistor according to a first embodiment of the present invention will be described.

The TFT device is a three-terminal device including a gate terminal, a source terminal, and a drain terminal. A semiconductor thin film formed on a dielectric substrate such as a plastic film substrate is used as a channel layer through which electrons or holes move. With this structure, the TFT device is an active device having a function of controlling a current flowing into the channel layer according to a voltage applied to the gate terminal to switch a current flowing between the source terminal and the drain terminal.

The TFT device which can be used here is, for example, a device having a stagger (top gate) structure in which a gate dielectric film and a gate terminal are formed on a semiconductor channel layer in this order or a device having an inverse stagger (bottom gate) structure in which a gate dielectric film and a semiconductor channel layer are formed on a gate terminal in this order.

In the present invention, an oxide thin film is used as the channel layer of the TFT device. The oxide thin film used as the channel layer is a transparent oxide thin film containing In, M, Zn, and O, where M represents at least one of Ga, Al, and Fe. The electron carrier concentration of the oxide thin film is desirably lower than 10¹⁸/cm³ and the electron mobility thereof is preferably. set to a value exceeding 1 cm²/(V·seconds). When the thin film is used for the channel layer, it is possible to produce a TFT which has such transistor characteristics that the gate current in an off state is smaller than 0.1 microamperes to be a normally-off transistor and that the on-off ratio exceeds 10³, and which is transparent to visual light.

When the TFT in which the transparent oxide thin film is used as the channel layer is to be produced, it is desirable to use a yttrium oxide (Y₂O₃) as the gate dielectric film. It is also preferable that a material including at least one selected from the group consisting of Y₂O₃, Al₂O₃, HfO₂, and TiO₂ be used for the gate dielectric film.

According to a mode of the present invention, after the TFT device is manufactured, the protective film is formed on the TFT device so as to cover the channel layer.

According to a mode of the present invention, the metal oxide film containing at least one kind of metal element can be used as the protective film formed on the TFT device. In this case, it is more preferable that the protective film to be used be the metal oxide film including at least one selected from the group consisting of Al₂O₃, Ga₂O₃, In₂O₃, MgO, CaO, SrO, BaO, ZnO, Nb₂O₅, Ta₂O₅, TiO₂, ZrO₂, HfO₂, CeO₂, Li₂O, Na₂O, K₂O, Rb₂O, Sc₂O₃, Y₂O₃, La₂O₃, Nd₂O₃, Sm₂O₃, Gd₂O₃, Dy₂O₃, Er₂O₃, and Yb₂O₃.

It is preferable that a sputtering method be used as a method of forming the metal oxide thin film as the protective film on the TFT. According to a preferable mode, an deposition method such as deposition using resistance heating, laser deposition, or electron beam deposition is used. According to another preferable mode, a chemical vapor deposition method (CVD method) is used.

It is preferable that a temperature at which the metal oxide film is formed as the protective film on the TFT using the above-mentioned method be equal to or smaller than 200° C.

As a result, the effect that the TFT operation is not influenced by an atmosphere and thus stable operation can be performed without causing unstable operation due to a change in atmosphere is obtained.

### Second Embodiment

Next, a second embodiment of the present invention will be described. According to this embodiment, a film including at least one selected from the group consisting of a silicon nitride (SiNx), a silicon oxide (SiOx), and a silicon oxynitride (SiOxNy) can be used as the protective film formed on the TFT device.

It is preferable that a CVD method be used as a method of forming a silicon nitride film, a silicon oxide film, or a silicon carbide film as the protective film on the TFT. According to a preferable mode, an deposition method such as deposition using resistance heating, laser deposition, or electron beam deposition is used. According to another preferable mode, a sputtering method is used. Above all, the CVD method is most preferably used to form the silicon nitride film (SiNx), the silicon oxide film (SiOx), or the silicon oxynitride film (SiOxNy).

It is preferable that a temperature at which the film including at least one selected from the group consisting of the silicon nitride, the silicon oxide, and the silicon oxynitride is formed as the protective film on the TFT using the above-mentioned method be equal to or lower than 200° C.

As a result, the effect that the TFT operation is not influenced by an atmosphere and thus stable operation can be performed without causing unstable operation due to a change in atmosphere is obtained.

Note that the SiNx film used as the protective film is normally formed at 350° C. or higher by a plasma CVD method with SiH₄ and NH₃ introduced. The SiOxNy film is normally formed in the same manner with SiH₂, NH₂ and O₂ introduced.

In recent years, a method using a catalyst, a plasma conduction, or the like has been studied to conduct research and develop on a low-temperature process of the SiNx film. As compared with an SiNx film formed at 350° C., an SiNx film formed at 200° C. or lower becomes a film having a low density as a whole because microvoids or the like are produced. However, a low-temperature formed SiNx film serving as the protective film for a device such as the TFT, which is formed on a flexible substrate, is more resistant to bending than a conventional SiNx protective film, because a stress such as bending is reduced by the microvoids or the like. Therefore, the low-temperature formed SiNx film is suitable as the protective film for a flexible device.

When the SiOx film is to be formed as the protective film at low temperatures, plasma CVD is generally performed using a tetraethoxysilane (TEOS, Si(OC₂H₅)₄) gas while introducing O₂ or O₃. When the film formation temperature is low, the microvoids or the like are produced as in the case where the SiNx film is formed, so that the SiOx becomes a low density. Undecomposed organic groups (alkoxyl groups) simultaneously remain without complete decompression, with the result that incomplete organic substance groups or incomplete organic substance cross-links exist in the film. The organic substances have properties of reducing the stress such as bending, so that the resistance of the protective film to, for example, bending thereof is increased as in the case of the microvoids or the like. Therefore, the low-temperature formed SiNx film is suitable as the protective film for the flexible device because the density is low but the resistance to the bending stress or the like is high as compared with the conventional SiOx film.

The above-mentioned points are expected for not only the SiNx film and the SiOx film but also for other protective films formed at a film formation temperature of 200° C. or lower.

### Third Embodiment

In a third embodiment of the present invention, an organic substance film can be used as the protective film formed on the TFT device. In this case, according to a preferable mode, a polyimide film is used as the organic substance film. According to another preferable mode, a fluorinated organic substance resin film such as a silicone film is used as the organic substance film.

It is preferable that a solution applying method of applying a solution and then performing drying or heating to form a film be used as a method of forming the organic substance film as the protective film on the TFT.

Further, it is preferable that a temperature at which the organic substance film is formed as the protective film on the TFT using the above-mentioned method be equal to or lower than 200° C.

Therefore, the effect that the TFT operation is not influenced by an atmosphere and thus stable operation can be performed without causing unstable operation due to a change in atmosphere is obtained.

### Fourth Embodiment

In a fourth embodiment of the present invention, a multilayer film comprised of an organic substance film and a metal film is used as the protective film formed on the TFT device. In this case, according to a preferable mode, a polyimide film is used as the organic substance film. According to another preferable mode, a fluorinated organic substance resin film such as a silicone film is used as the organic substance film. According to a preferable mode, an aluminum film is used as the metal film.

When the multilayer film including the organic substance film and the metal film is to be produced, it is preferable that the organic substance film be first formed. on the TFT and then the metal film be laminated thereon. According to a preferable mode, the number of laminations in which the organic substance film and the metal film are layered is approximately one or two.

It is preferable that a solution applying method of applying a solution and then performing drying or heating to form a film be used as a method of forming the organic substance film as the protective film on the TFT. When the metal film is to be formed, it is preferable to use a sputtering method or an deposition method such as deposition using resistance heating, laser deposition, or electron beam deposition.

It is preferable that a temperature at which the multilayer film including the organic substance film and the metal film is formed as the protective film on the TFT using the above-mentioned method be equal to or lower than 200° C.

Therefore, the effect that the TFT operation is not influenced by an atmosphere and thus stable operation can be performed without causing unstable operation due to a change in atmosphere is obtained.

### EXAMPLES

Hereinafter, the present invention will be described in more detail with reference to examples. Note that the present invention is not limited to the following examples.

### Example 1

### TFT having Protective Film composed of Metal Oxide

1) Manufacturing of TFT Device

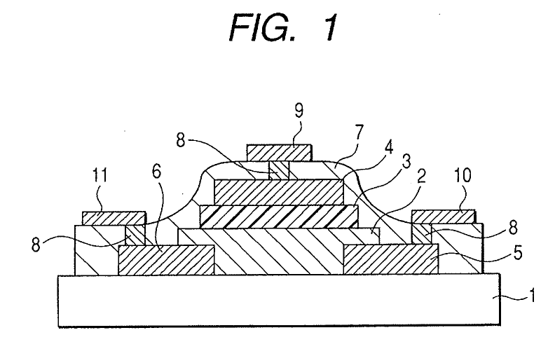

A metal-insulator-semiconductor field effect transistor (MISFET) device of the top gate type as shown in FIG. 1 was manufactured as a TFT device according to this example.

In manufacturing the TFT, first, a polyethylene terephthalate (PET) film was used as a plastic film substrate 1. An ITO film having a thickness of 50 nm was deposited on the plastic film substrate 1 by a DC magnetron sputtering method using a polycrystalline material of In₂O₃ to which SnO₂ was added at 5% as a target. The deposited ITO film was subjected to a photolithography method and a lift-off method to form a drain electrode 5 and a source electrode 6.

Subsequently, an In—Ga—Zn—O oxide semiconductor thin film having a thickness of 50 nm was deposited as a channel layer 2 by an RF magnetron sputtering method using a ceramic having a composition of InGaO₃(ZnO) as a target. The oxygen partial pressure in the chamber was 0.5 Pa and the substrate temperature was 25° C. The deposited In—Ga—Zn—O oxide semiconductor thin film was processed to a suitable size by a photolithography method and a lift-off method.

Then, a Y₂O₃ film having a thickness of 100 nm was formed on the entire surface by an electron beam deposition method and processed by a photolithography method and a lift-off method to form a gate dielectric film 3. After that, an ITO film is formed on the entire surface and processed by the photolithography method and the lift-off method to form a gate electrode 4.

The TFT device was manufactured by the above-mentioned method.

2) Formation of Protective Film on TFT

The substrate on which the TFT device was manufactured was heated at 150° C. for 20 minutes in a dry atmosphere to remove absorbed moisture and the like. Immediately after that, the substrate on which the TFT device was formed was introduced into an electron beam deposition apparatus. An Al₂O₃ film having a thickness of 200 nm was deposited as a protective film 7 by electron beam deposition. At this time, the film formation temperature was room temperature. Part of the deposited Al₂O₃ on the gate electrode 4, the drain electrode 5, and the source electrode 6 was removed by a photolithography method and an argon milling method to form contact holes 8.

Then, an ITO film having a thickness of 300 nm was deposited on the entire surface to fill the contact holes 8 and processed to a suitable size by a photolithography method and a wet etching method. Thus, a gate terminal 9, a drain terminal 10, and a source terminal 11 were formed on the protective film of Al₂O₃.

3) Characteristic Evaluation of TFT Device

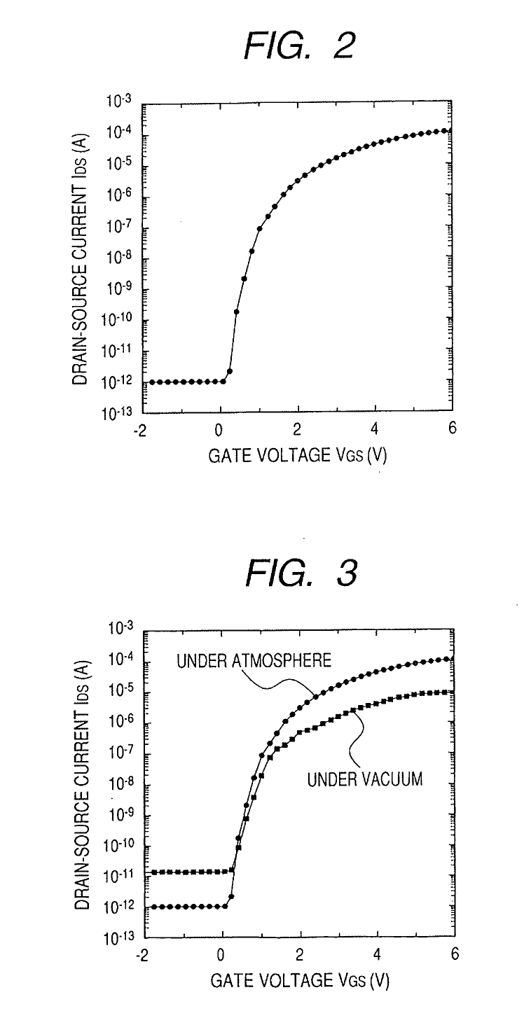

FIG. 2 shows transfer characteristics of the TFT device which was measured at room temperature in the atmosphere. As is apparent from FIG. 2, the drain-source current I_{DS} of the TFT device on which the protective film was formed increased with an increase in the gate voltage V_{GS} thereof. The on/off current ratio is equal to or larger than 10⁶. The field-effect mobility was calculated from the output characteristics. As a result, a field-effect mobility of approximately 7 cm² (Vs)⁻¹ was obtained in the saturation region. The TFT device was placed in a vacuum chamber and measurement is performed thereon in vacuum. A change in characteristics is not observed.

For comparison, FIG. 3 shows results obtained by measurement under atmosphere and vacuum of transfer characteristics of a TFT device which was manufactured in the same manner as in the case of the above-mentioned TFT device except that the protective film was not formed therein. As is apparent from FIG. 3, when the TFT device on which the protective film was not formed was under an atmosphere, the result obtained by measurement thereon was similar to the result obtained by measurement (FIG. 2) on the TFT device on which the protective film was formed. However, when the TFT device on which the protective film was not formed was under vacuum, both the on-current and the off-current were reduced to approximately one-tenth. The field-effect mobility is 7 cm² (Vs)⁻¹ under the atmosphere and approximately 1 cm² (Vs)⁻¹ under vacuum.

The protective film for the above-mentioned TFT device was formed at low temperatures, for example, room temperature, so microvoids were observed in the protective film. It was confirmed that the resistance of the protective film to bending stress was larger than that of a protective film formed at a film formation temperature exceeding 200° C. because of the presence of the microvoids or the like.

### Example 2

### TFT having Protective Film including Silicon Nitride

1) Manufacturing of TFT Device

A top gate type MISFET device shown in FIG. 1 was manufactured as a TFT device according to this example.

In manufacturing the TFT, first, a polyethylene terephthalate (PET) film was used as a plastic film substrate 1. An ITO film having a thickness of 50 nm was deposited on the plastic film substrate 1 by a DC magnetron sputtering method using a polycrystalline material of In₂O₃ to which SnO₂ is added at 5% as a target. The deposited ITO film was subjected to a photolithography method and a lift-off method to form a drain electrode 5 and a source electrode 6.

Subsequently, an In—Ga—Zn—O oxide semiconductor thin film having a thickness of 50 nm was deposited as a channel layer 2 by an RF magnetron sputtering method using a ceramic having a composition of InGaO₃(ZnO) as a target. The oxygen partial pressure in the chamber was 0.5 Pa and the substrate temperature was 25° C. The deposited In—Ga—Zn—O oxide semiconductor thin film was processed to a suitable size by a photolithography method and a lift-off method.

Then, a Y₂O₃ film having a thickness of 100 nm was formed on the entire surface by an electron beam deposition method and processed by a photolithography method and a lift-off method to form a gate dielectric film 3. After that, an ITO film is formed on the entire surface and processed by a photolithography method and a lift-off method to form a gate electrode 4.

The TFT device is manufactured by the above-mentioned method.

2) Formation of Protective Film on TFT

The substrate on which the TFT device was manufactured was heated at 150° C. for 20 minutes in a dry atmosphere to remove absorbed moisture and the like. Immediately after that, the substrate in which the TFT device was formed was introduced into a plasma CVD apparatus. An SiNx film having a thickness of 200 nm was deposited as a protective film 7 by a plasma CVD method using SiH₄ and NH₃ as raw gases. At this time, the film formation temperature was 100° C.

Part of the deposited SiNx film on the gate electrode 4, the drain electrode 5, and the gate electrode 6 was removed by a photolithography method and an argon milling method to form contact holes 8. Then, an ITO film having a thickness of 300 nm was deposited on the entire surface to fill the contact holes 8 and processed to a suitable size by a photolithography method and a wet etching method. As a result, a gate terminal 9, a drain terminal 10, and a source terminal 11 were formed on the protective film of SiNx.

3) Characteristic Evaluation of TFT Device

FIG. 2 shows the transfer characteristic of the TFT device which was measured at room temperature in the atmosphere. As is apparent from FIG. 2, the drain-source current I_{DS} of the TFT device on which the protective film was formed increased with an increase in the gate voltage V_{GS} thereof. The on/off current ratio was equal to or larger than 10⁶. The field-effect mobility was calculated from the output characteristics. As a result, a field-effect mobility of approximately 7 cm² (Vs)⁻¹ was obtained in the saturation region. The TFT device is placed in a vacuum chamber and measurement was performed thereon in vacuum. A change in characteristics was not observed.

For comparison, FIG. 3 shows results obtained by measurement under atmosphere and vacuum of transfer characteristics of a TFT device which was manufactured in the same manner as in the case of the above-mentioned TFT device except that the protective film was not formed thereon. As is apparent from FIG. 3, when the TFT device on which the protective film was not formed was under the atmosphere, the result obtained by measurement thereon was similar to the result obtained by measurement (FIG. 2) on the TFT device on which the protective film is formed. However, when the TFT device on which the protective film was not formed was under vacuum, both the on-current and the off-current were reduced to approximately one-tenth. The field-effect mobility was 7 cm² (Vs)⁻¹ under the atmosphere and approximately 1 cm² (Vs)⁻¹ under vacuum.

The protective film for the above-mentioned TFT device was formed at low temperatures, for example, 100° C., so microvoids was observed in the protective film. It was confirmed that the resistance of the protective film to bending stress was larger than that of a protective film formed at a film formation temperature exceeding 200° C. because of the presence of the microvoids or the like.

### Example 3

### TFT having Protective Film comprised of Organic Substance

1) Manufacturing of TFT Device

A top gate type MISFET device shown in FIG. 1 was manufactured as a TFT device according to this example.

In manufacturing the TFT, first, a polyethylene terephthalate (PET) film was used as a plastic film substrate 1. An ITO film having a thickness of 50 nm is deposited on the plastic film substrate 1 by a DC magnetron sputtering method using a polycrystalline material of In₂O₃ to which SnO₂ was added at 5% as a target. The deposited ITO film was subjected to a photolithography method and a lift-off method to form a drain electrode 5 and a source electrode 6.

Subsequently, an In—Ga—Zn—O oxide semiconductor thin film having a thickness of 50 nm was deposited as the channel layer 2 by an RF magnetron sputtering method using a ceramic having a composition of InGaO₃(ZnO) as a target. The oxygen partial pressure in a chamber was 0.5 Pa and the substrate temperature was 25° C. The deposited In—Ga—Zn—O oxide semiconductor thin film was processed to a suitable size by a photolithography method and a lift-off method.

Then, a Y₂O₃ film having a thickness of 100 nm was formed on the entire surface by an electron beam deposition method and processed by a photolithography method and a lift-off method to form a gate dielectric film 3. After that, an ITO film is formed on the entire surface and processed by a photolithography method and a lift-off method to form a gate electrode 4.

The TFT device was manufactured by the above-mentioned method.

2) Formation of Protective Film on TFT

The substrate on which the TFT device was manufactured was heated at 150° C. for 20 minutes in a dry atmosphere to remove absorbed moisture and the like. Immediately after that, a solution containing a silicone resin was applied onto the substrate on which the TFT device was formed by a spin coating method. After the application, the substrate was dried at 100° C. in a dry atmosphere to deposit a silicone resin film having a thickness of 200 nm as a protective film 7. Part of the deposited silicone resin film on the gate electrode 4, the drain electrode 5, and the source electrode 6 was removed by a photolithography method and etching using an organic solvent to form contact holes 8.

Then, an ITO film having a thickness of 300 nm was deposited on the entire surface to fill the contact holes 8 and processed to a suitable size by a photolithography method and a wet etching method. Therefore, a gate terminal 9, a drain terminal 10, and a source terminal 11 are formed on the protective film 7.

3) Characteristic Evaluation of TFT Device

FIG. 2 shows the transfer characteristics of the TFT device which was measured at room temperature in the atmosphere in the case where the drain voltage thereof was +4 volts. As is apparent from FIG. 2, the drain-source current I_{DS} of the TFT device on which the protective film was formed increased with an increase in the gate voltage V_{GS} thereof. The on/off current ratio was equal to or larger than 10⁶. The field-effect mobility was calculated from the output characteristics. As a result, a field-effect mobility of approximately 7 cm² (Vs)⁻¹ was obtained in the saturation region. The TFT device was placed in a vacuum chamber and measurement was performed thereon in vacuum. A change in characteristics was not observed.

For comparison, FIG. 3 shows results obtained by measurement under atmosphere and vacuum of transfer characteristics of a TFT device which was manufactured in the same manner as in the case of the above-mentioned TFT device except that the protective film was not formed thereon. As is apparent from FIG. 3, when the TFT device on which the protective film was not formed was under the atmosphere, the result obtained by measurement thereon was similar to the result obtained by measurement (FIG. 2) on the TFT device on which the protective film was formed. However, when the TFT device on which the protective film was not formed was under vacuum, both the on-current and the off-current were reduced to approximately one-tenth. The field-effect mobility was 7 cm² (Vs)⁻¹ under the atmosphere and approximately 1 cm² (Vs)⁻¹ under vacuum.

The protective film for the above-mentioned TFT device was formed at low temperatures, for example, 100° C., so microvoids were observed in the protective film. It was confirmed that the resistance of the protective film to bending stress was larger than that of a protective film formed at a film formation temperature exceeding 200° C. because of the presence of the microvoids or the like.

### Example 4

### TFT having Protective Film of Multilayer Film comprised of Organic Substance Film and Metal Film

1) Manufacturing of TFT Device

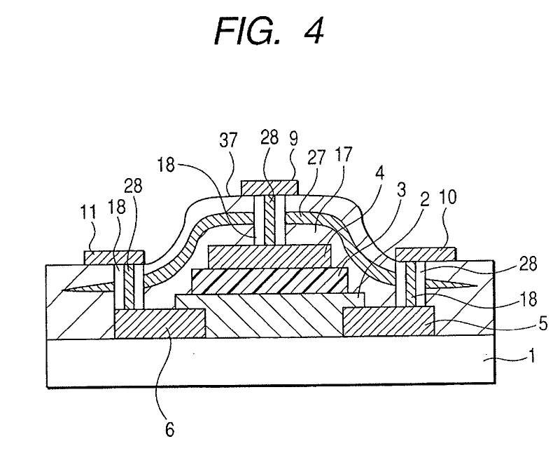

A top gate type MISFET device as shown in FIG. 4 was manufactured as a TFT device according to this example.

In manufacturing the TFT, first, a polyethylene terephthalate (PET) film was used as a plastic film substrate 1. An ITO film having a thickness of 50 nm was deposited on the plastic film substrate 1 by a DC magnetron sputtering method using a polycrystalline material of In₂O₃ to which SnO₂ was added at 5% as a target. The deposited ITO film was subjected to a photolithography method and a lift-off method to form a drain electrode 5 and a source electrode 6.

Subsequently, an In—Ga—Zn—O oxide semiconductor thin film having a thickness of 50 nm was deposited as the channel layer 2 by an RF magnetron sputtering method using a ceramic having a composition of InGaO₃(ZnO) as a target. The oxygen partial pressure in the chamber was 0.5 Pa and the substrate temperature was 25° C. The deposited In—Ga—Zn—O oxide semiconductor thin film is processed to a suitable size by a photolithography method and a lift-off method.

Then, a Y₂O₃ film having a thickness of 100 nm was formed on the entire surface by an electron beam deposition method and processed by a photolithography method and a lift-off method to form a gate dielectric film 3. After that, an ITO film was formed on the entire surface and processed by a photolithography method and a lift-off method to form a gate electrode 4.

The TFT device was manufactured by the above-mentioned method.

2) Formation of Protective Film on TFT

The substrate on which the TFT device was manufactured was heated at 150° C. for 20 minutes in a dry atmosphere to remove absorbed moisture and the like. Immediately after that, a solution containing a silicone resin was applied onto the substrate on which the TFT device was formed by a spin coating method. After the application, the substrate was dried at 100° C. in a dry atmosphere to deposit a silicone resin film having a thickness of 100 nm. Then, the substrate is introduced into an electron beam deposition apparatus and an Al film having a thickness of 100 nm was deposited thereon by electron beam deposition. At this time, the film formation temperature was room temperature.

A multilayer protective film comprised of an organic substance film 17 and a metal film 27 was formed by the above-mentioned method.

Part of the deposited multilayer protective film including the organic substance film 17 and the metal film 27, on the gate electrode 4, the drain electrode 5, and the source electrode 6, was removed by etching using a photolithography method and an argon milling method to form through-holes 18.

Then, a silicone resin film having a thickness of 100 nm was deposited as a dielectric film 37 on the entire surface in the same manner as in the case of the organic substance film 17. Part of the deposited dielectric film 37 in the inner side of the through-holes 18 was removed by a photolithography method and etching using an organic solvent to form contact holes 28.

An ITO film having a thickness of 400 nm was deposited on the entire surface to fill the contact holes 28 and processed to a suitable size by a photolithography method and a wet etching method. As a result, a gate terminal 9, a drain terminal 10, and a source terminal 11 were formed on the dielectric film 37.

3) Characteristic Evaluation of TFT Device

FIG. 2 shows the transfer characteristics of the TFT device which was measured at room temperature in the atmosphere. As is apparent from FIG. 2, the drain-source current I_{DS} of the TFT device on which the protective film was formed increases with an increase in the gate voltage V_{GS} thereof. The on/off current ratio was equal to or larger than 10⁶. The field-effect mobility was calculated from the output characteristics. As a result, a field-effect mobility of approximately 7 cm² (Vs)⁻¹ is obtained in the saturation region. The TFT device is placed in a vacuum chamber and measurement is performed thereon in vacuum. A change in characteristic is not observed.

For comparison, FIG. 3 shows results obtained by measurement under atmosphere and vacuum of transfer characteristics of a TFT device which was manufactured in the same manner as in the case of the above-mentioned TFT device except that the protective film was not formed thereon. As is apparent from FIG. 3, when the TFT device on which the protective film was not formed was under the atmosphere, the result obtained by measurement thereon was similar to the result obtained by measurement (FIG. 2) on the TFT device on which the protective film is formed. However, when the TFT device on which the protective film was not formed is under vacuum, both the on-current and the off-current are reduced to approximately one-tenth. The field-effect mobility was 7 cm² (Vs)⁻¹ under the atmosphere and approximately 1 cm² (Vs)⁻¹ under vacuum.

The protective film for the above-mentioned TFT device was formed at low temperatures, for example, room temperature, so microvoids were observed in the protective film. It was confirmed that the resistance of the protective film to bending stress was larger than that of a protective film formed at a film formation temperature exceeding 200° C. because of the presence of the microvoids or the like.

### Example 5

### TFT having Gate Dielectric Film of Aluminum Oxide

In this example, a TFT was manufactured in which an Al₂O₃ film having a thickness of 100 nm, instead of the Y₂O₃ film having the thickness of 100 nm in each of Examples 1 to 4, was deposited as a gate dielectric film by an electron beam deposition method. The other structures of the TFT device and the manufacturing method thereof were identical to those in each of Examples 1 to 4. The protective film was formed on the manufactured TFT device and then characteristics of the TFT device was evaluated. As a result, the same performance and stability as those of the TFT having the gate dielectric film of Y₂O₃ were obtained.

### Example 6

### TFT having Gate Dielectric Film of Hafnium Oxide

In this example, a TFT was manufactured in which an HfO₂ film having a thickness of 100 nm, instead of the Y₂O₃ film having the thickness of 100 nm in each of Examples 1 to 4, was. deposited as a gate dielectric film by an electron beam deposition method. The other structures of the TFT device and the manufacturing method thereof were identical to those in each of Examples 1 to 4. A protective film was formed on the manufactured TFT device and then characteristics of the TFT device were evaluated. As a result, the same performance and stability as those of the TFT having the gate dielectric film of Y₂O₃ were obtained.

### Example 7

### TFT having Gate Dielectric Film of Zirconium Oxide

In this example, a TFT was manufactured in which a ZrO₂ film having a thickness of 100 nm, instead of the Y₂O₃ film having the thickness of 100 nm in each of Examples 1 to 4, was deposited as a gate dielectric film by an electron beam deposition method. The other structures of the TFT device and the manufacturing method thereof were identical to those in each of Examples 1 to 4. The protective film was formed on the manufactured TFT device and then characteristics of the TFT device were evaluated. As a result, the same performance and stability as those of the TFT having the gate dielectric film of Y₂O₃ were obtained.

### Example 8

### TFT in which Titanium Oxide is used for Gate Dielectric Film

In this example, a TFT was manufactured in which a TiO₂ film having a thickness of 100 nm, instead of the Y₂O₃ film having the thickness of 100 nm in each of Examples 1 to 4, was deposited as a gate dielectric film by an electron beam deposition method. The other structures of the TFT device and a manufacturing method thereof were identical to those in each of Examples 1 to 4. The protective film was formed on the manufactured TFT device and then characteristics of the TFT device were evaluated. As a result, the same performance and stability as those of the TFT having the gate dielectric film of Y₂O₃ were obtained.

In each of the examples, the protective film was formed on the entire region of the TFT device. However, the present invention is not limited to such case. It is only necessary to cover at least an oxide semiconductor channel layer of the TFT device.

In each of the examples, the plastic film substrate is used as the dielectric substrate. However, the present invention is not limited to the plastic film substrate, and for example, a glass substrate can be used.

Furthermore, a PET film is used as the plastic film substrate in each of the examples, but the present invention is not limited thereto. For example, in addition to PET, at least one kind of a thermoplastic resin selected from the group consisting of triacetate, diacetate, cellophane, polyether sulfone, polyetherether sulfone, polysulfone, polyether imide, polycarbonate, polyester, polyvinyl alcohol, polyarylate, polymethyl methacrylate, vinylidene fluoride, polystyrene, an AS resin, an ABS resin, polyethylene, polypropylene, a vinyl chrolide resin, a methacrylate resin, polyethylene naphthalate, polyamide, polyacetal, modified polypheylene ether, polypheylene sulfide, polyamideimide, polyimide, polyphtalamide, a cyclic polyolefin polymer, a cycloolefin polymer, polyetherether ketone, and a liquid crystal polymer can be used as a thermoplastic resin.

In each of the examples, the example in which an amorphous oxide containing In, Ga, and Zn is used as an oxide semiconductor containing In, M, Zn, and O, where M represents at least one of Ga, Al, and Fe, is described. In the present invention, an amorphous oxide containing at least one kind of element selected from the group consisting of Sn, In, and Zn can be used.

When Sn is to be selected as at least one of the constituent elements of the amorphous oxide, Sn can be replaced by Sn₁₋ₓM4ₓ, where 0<x<1, and M4 is selected from the group consisting of Si, Ge, and Zr, each of which is a group IV element whose atomic number is smaller than that of Sn.

When In is to be selected as at least one of the constituent elements of the amorphous oxide, In can be replaced by In_{1-yx}M3_{y}, where 0<y<1, and M3 is selected from the group consisting of B, Al, Ga, and Y, each of which is a group III element whose atomic number is smaller than that of Lu or In.

When Zn is to be selected as at least one of the constituent elements of the amorphous oxide, Zn can be replaced by Zn_{1-z}M2_{z}, where 0<Z<1, and M2 is selected from the group consisting of Mg and Ca, each of which is a group II element whose atomic number is smaller than that of Zn.

Specific examples of the amorphous material which can be applied in the present invention include an Sn—In—Zn oxide, an In—Zn—Ga—Mg oxide, an In oxide, an In—Sn oxide, an In—Ga oxide, an In—Zn oxide, a Zn—Ga oxide, and an Sn—In—Zn oxide. The composition ratio of the constituent materials is not necessarily set to 1:1. When Zn or Sn is solely used, it may be difficult to produce an amorphous phase. However, when In is added, it is easy to produce an amorphous phase. For example, in the case of In—Zn systems, the ratio of the number of atoms except oxygen is preferably adjusted to obtain a composition in which the concentration of In is equal to or larger than approximately 20 atom %. In the case of Sn—In systems, the ratio of the number of atoms except oxygen is preferably adjusted to obtain a composition in which the concentration of In is equal to or larger than approximately 80 atom %. In the case of Sn—In—Zn systems, the ratio of the number of atoms except oxygen is preferably adjusted to obtain a composition in which the concentration of In is equal to or larger than approximately 15 atom %.

When a clear diffraction peak is not detected (that is, halo pattern is observed) when X-ray diffraction is performed on a thin film as a measurement target at a low incident angle such as an incident angle of approximately 0.5 degrees, it can be determined that the thin film is amorphous. When any one of the above-mentioned materials is used for the channel layer of the field effect transistor, the present invention does not exclude that the channel layer contains a constituent material in a microcrystal state.

The oxide semiconductor thin film transistor according to the present invention, in which an oxide semiconductor containing In, M, Zn, and O, where M represents at least one of Ga, Al, and Fe, is used for the channel, can be utilized as a switching element for an LCD or an organic EL display. The oxide semiconductor thin film transistor according to the present invention can be widely applied to a flexible display in which a semiconductor thin film is formed on a flexible material represented by a plastic film, an IC card, an ID tag, and the like.

As many apparently widely different embodiments of the present invention can be made without departing from the spirit and scope thereof, it is to be understood that the invention is not limited to the specific embodiments thereof except as defined in the claims.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2005-258276, filed Sep. 6, 2005, which is hereby incorporated by reference herein in its entirety.

What is claimed is:

1. A thin film transistor, comprising:
a channel layer comprised of an oxide semiconductor containing In, M, Zn, and O, where M represents at least one selected from the group consisting of Ga, Al, and Fe; and
a protective film that covers the channel layer.

2. A thin film transistor according to claim 1, wherein the protective film is a metal oxide film containing at least one kind of metal element.

3. A thin film transistor according to claim 1, wherein the protective film is a film comprised of at least one selected from the group consisting of a silicon nitride, a silicon oxide, and a silicon oxynitride.

4. A thin film transistor according to claim 1, wherein the protective film is an organic substance film.

5. A thin film transistor according to claim 1, wherein the protective film is a multilayer film comprised of an organic substance film and a metal film.

6. A thin film transistor according to claim 1, wherein the thin film transistor further comprises a gate dielectric film composed of a yttrium oxide.

7. A thin film transistor according to claim 1, wherein the thin film transistor further comprises a gate dielectric film which includes at least one selected from the group consisting of a yttrium oxide, an aluminum oxide, a hafnium oxide, a zirconium oxide, and a titanium oxide.

8. A thin film transistor according to claim 1, wherein the protective film comprises a microvoid formed therein.
